(19) United States
(12) Patent Application Publication
(10) Pub. No.: US 2006/0043531 A1
(43) Pub. Date: Mar. 2, 2006

(54) Reduction of source and drain parasitic capacitance in CMOS devices

(75) Inventors: Yuri Erokhin, Newburyport, MA (US); Ukyo Jeong, Andover, MA (US); Jay T. Scheuer, Rowley, MA (US); Steven R. Walther, Andover, MA (US)

Correspondence Address: Mark A. Superko, Esq.;Varian Semiconductor Equipment, Inc., 35 Dory Road, Glouster, MA, 01930, US

(73) Assignee: Varian Semiconductor Equipment Associates, Inc., Gloucester, MA (US)

(21) Appl. No.: 10/928,555

(22) Filed: Aug. 27, 2004

(51) Int. Cl. H01L 29/788

(52) U.S. Cl. 257/607

(57) ABSTRACT

A method for fabricating a semiconductor-based device includes providing a doped semiconductor substrate, introducing a second dopant into the substrate to define a pn junction, and introducing a neutralizing species into the substrate in the neighborhood of the pn junction to reduce a capacitance associated with the pn junction. A semiconductor-based device includes a semiconductor substrate having first and second dopants, and a neutralizing species. The first and second dopants define a pn junction, and the neutralizing species neutralizes a portion of the first dopant in the neighborhood of the pn junction to decrease a capacitance associated with the pn junction.

### BACKGROUND OF INVENTION

1. Field of Invention

The invention is related to semiconductor-based devices, and, in particular, to semiconductor-based devices and methods of fabrication that provide reduced parasitic capacitances.

2. Discussion of Related Art

Integrated circuits typically include inherent parasitic elements that are detrimental to circuit performance. For example, the pn junctions of bipolar transistors and metal-oxide-semiconductor (MOS) transistors have a capacitance when in a reversed-bias condition, and can thus act as parasitic capacitors. As another example, interconnect lines can act as capacitor electrodes, again giving rise to parasitic capacitors. Such capacitive elements are termed “parasitic” because they can cause undesirable effects. The parasitic capacitive elements can, for example, introduce circuit delays. For example, in a logic circuit, a parasitic input capacitance of a driven cell can act as a load capacitance of a driving cell, and can thus affect a delay time of the driving cell.

In complementary-MOS (CMOS) circuits, a MOS transistor's source and drain exhibit capacitances associated with the reverse-biased pn junctions defined between the source and the substrate, and between the drain and the substrate. Typically, these pn junctions are reverse biased to isolate the source and the drain from the underlying portions of the substrate. The capacitance of the reverse-biased junctions is determined in part by the depletion widths of the junctions.

To form a N-type MOS transistor, for example, a p-type substrate, doped with a p-type dopant such as boron (B), can be implanted in selected areas with a n-type dopant, such as arsenic (As) or phosphorus (P) to form relatively heavily doped source and drain n-type regions. Typically, the implanted n-type dopant concentration is greater, in the source and drain regions, than the p-type doping of the substrate, thus converting the source and drain regions to the required n-type state. The pn junctions that separate the n-type source and drain regions from the underlying substrate p-type portion can thus act as parasitic capacitive elements. Sources and drains can produce as much as 30%, or more, of the total parasitic capacitance of an integrated circuit. Reduction of this capacitance can provide increased operating speed and reduced power consumption.

To reduce source and drain parasitic capacitance, integrated circuits can be fabricated on, for example, silicon-on-insulator (SOI) wafers. Unfortunately, SOI wafers are more expensive than traditional silicon wafers. Further, use of SOI wafers can require modified circuit designs, can incur SOI-specific design problems, such as floating-body and hysteresis effects, and can present problems associated with the greater defect densities in SOI wafers in comparison to standard silicon wafers, which can reduce device fabrication yield and thus increase device cost.

### SUMMARY OF INVENTION

The invention arises in part from the realization that the parasitic capacitance associated with a pn junction can be reduced by locally neutralizing a portion of a dopant to increase a depletion width associated with the pn junction. The dopant portion can be neutralized, for example, by passivating some of the dopant residing at substitutional lattice sites and/or by displacing some of the electrically active dopant from substitutional lattice sites respectively with passivating species and/or displacing species. For example, hydrogen can provide passivation of a portion of the boron in a substrate in the vicinity of a pn junction to extend a depletion width of the pn junction between a n-type source or drain region and the underlying p-type substrate region. Moreover, hydrogen, for example, can conveniently be co-implanted with a dopant, for example, by plasma implantation.

A plasma can be formed from an implant material that includes both an implant species and a neutralizing species. Alternatively, a plasma can be formed from an implant material that includes an implant species, such as a dopant species, and from a neutralizing material that includes a neutralizing species. Thus, although not required, implantation of dopant species and neutralizing species can be contemporaneous.

In some embodiments of the invention, a dopant gas and a carrier gas are supplied to a plasma. The carrier gas can be selected to provide a species that can neutralize otherwise active dopant atoms. Dopant atoms may be neutralized by, for example, forming electronic bonds with a neutralizing species to passivate the dopant atoms, and/or by being displaced to interstitial lattice sites by the neutralizing species. The dopant and the neutralizing species can be implanted sequentially, or can be co-implanted from the same plasma. Thus the invention can be applied, for example, in plasma implantation-based systems. Plasma implantation systems that can benefit from features of the invention can utilize, for example, a pulsed or a continuous plasma.

Accordingly, in a first aspect, the invention features a method for fabricating a semiconductor-based device. The method includes providing a substrate that includes a semiconductor and a first dopant, introducing a second dopant into the substrate, and introducing a neutralizing species into the substrate. The first and second dopants define a pn junction in the substrate. The neutralizing species causes a reduction in a capacitance associated with the pn junction by reducing an active concentration of the first dopant in the neighborhood of the pn junction.

A dose of the neutralizing species can be selected to provide neutralization of less than all of the first dopant. For example, the dose can be selected to provide sufficient neutralizing species to reduce the active concentration of the first dopant by a factor in a range of about 20% to about 90%. The capacitance of the pn junction can be decreased by, for example, increasing a junction depletion width. The first dopant can be introduced into the semiconductor, for example, during growth, via diffusion, and/or via implantation.

In a second aspect, the invention features a semiconductor-based device. The device includes a substrate. The substrate includes a semiconductor, first and second dopants that define a pn junction, and a neutralizing species. The neutralizing species locally neutralizes a portion of the first dopant species to decrease a capacitance associated with the pn junction. The pn junction can be associated with a transistor.

### BRIEF DESCRIPTION OF DRAWINGS

The accompanying drawings, are not intended to be drawn to scale. In the drawings, each identical or nearly identical component that is illustrated in various figures is represented by a like numeral. For purposes of clarity, not every component may be labeled in every drawing. In the drawings:

FIG. 1 is a flowchart of an embodiment of a method fabricating a semiconductor-based device, according to principles of the invention.

FIG. 2a is cross-sectional diagram of an embodiment of semiconductor-based pn junction, according to principles of the invention.

FIG. 2b is cross-sectional diagram of an embodiment of semiconductor-based device, according to principles of the invention.

### DETAILED DESCRIPTION

This invention is not limited in its application to the details of construction and the arrangement of components set forth in the following description or illustrated in the drawings. The invention is capable of other embodiments and of being practiced or of being carried out in various ways. Also, the phraseology and terminology used herein is for the purpose of description and should not be regarded as limiting. The use of “including,” “comprising,” or “having,” “containing”, “involving”, and variations thereof herein, is meant to encompass the items listed thereafter and equivalents thereof as well as additional items.

The word “plasma,” is used herein in a broad sense to refer to a gas-like phase that can include any or all of electrons, atomic or molecular ions, atomic or molecular radical species (i.e., activated neutrals), and neutral atoms and molecules. A plasma typically has a net charge that is approximately zero. A plasma may be formed from one or more materials by, for example, ionizing and/or dissociating events, which in turn may be stimulated by a power source with, for example, inductive and/or capacitive coupling.

The phrase “plasma implantation” is used herein to refer to implantation techniques that utilize implantation from a plasma without the mass selection features of a traditional beam implanter. A plasma implanter typically involves both a substrate and a plasma in the same chamber. The plasma can thus be near to the substrate or immerse the substrate. Typically, a variety of species types from the plasma will implant into the substrate. As used herein, the word “species” can refer to atoms, molecules, or collections of same, which can be in a neutral, ionized, or excited state.

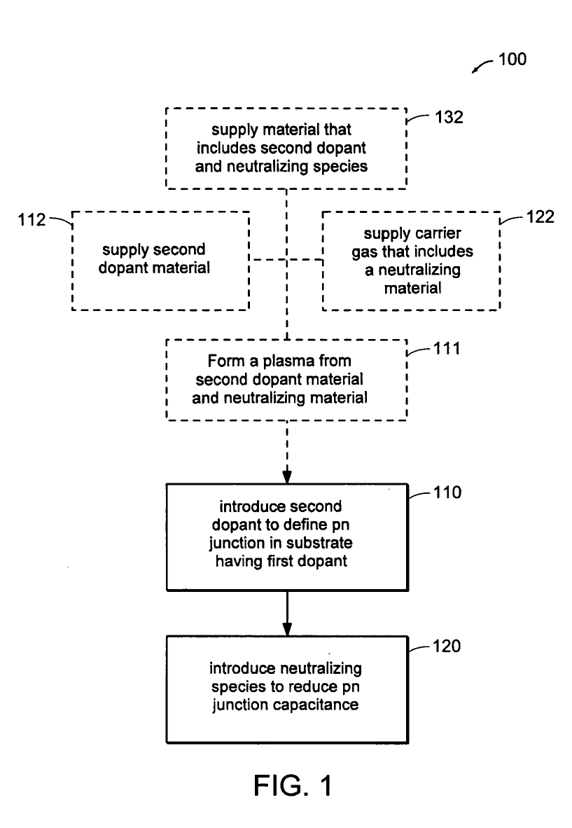

FIG. 1 is a flowchart of an embodiment of a method 100 for fabricating a semiconductor-based device, according to principles of the invention. A substrate is provided, and includes a semiconductor, such as silicon, and a first dopant to provide a p-type or n-type substrate. The method 100 includes introducing a second dopant into the substrate (Step 110) to define a pn junction in cooperation with the first dopant, and introducing a neutralizing species into the substrate (Step 120) to reduce a capacitance associated with the pn junction. The device can be, for example, a component of a circuit, such as a diode or a transistor. The transistor can be, for example, a MOS transistor or a bipolar transistor. Alternatively, the device can be a portion of a circuit, or a complete circuit.

The introduction of the second dopant (Step 110) leads to conversion of a portion of the substrate from p-type to n-type, or from n-type to p-type, in association with the types of the first and second dopants. A pn junction thus appears between the converted region and the adjacent substrate. The pn junction can be associated with, for example, a source and/or a drain of a transistor, for example, an MOS transistor.

A substrate can be, for example, a p-type or n-type silicon wafer. As known to one having skill in the semiconductor fabrication arts, such wafers can be manufactured by, for example, growing a silicon crystal with simultaneous incorporation, respectively, of a dopant, such as B, P, or As. Thus, a first dopant can be, for example, B for a p-type wafer, or P or As for an n-type wafer. Source and drain regions can then be formed in the wafer by, for example, respectively introducing (Step 110) a n-type dopant or a p-type dopant into the desired regions. The second dopant can be introduced (Step 110) by, for example, implantation, such as plasma implantation, or by diffusion.

In the following description, exemplary embodiments of the invention that refer to particular dopants and particular neutralizing species are not intended to be limiting with respect to those materials. It should be understood that principles of the invention may be applied to a broad range of implant materials and implant species. Accordingly, for simplicity, some of the described embodiments of the invention refer to a boron-doped substrate with As introduced to create source and drain regions for a transistor. Principles of the invention can be applied, however, to other materials and device structures to reduce junction capacitance.

Arsenic as a second dopant can be introduced into the substrate (Step 110) by, for example, diffusing or implanting As through the surface of the substrate. As known to one having ordinary skill in the semiconductor fabrication arts, one may commence fabrication of a MOS transistor by using a silicon substrate having a substantially uniform distribution of B dopant. The source and drain of a MOS transistor can then be formed by introducing As of a relatively high concentration into a region of the substrate. Since the As in the source and drain regions has a higher concentration than B in those regions, the source and drain regions are converted from p-type to n-type material.

Further, p-type MOS transistors can be formed in the same (p-type) substrate by, for example, first forming a well of n-type dopant in the p-type substrate. Source and drain regions may then be formed in the well by introducing p-type dopant to define p-type source and drain regions within the n-type well. Thus, principles of the invention can be applied, for example, to improve transistors formed in wells, as well as those that require fewer doping steps during fabrication.

The neutralizing species can be introduced to reduce the capacitance of the pn junction (Step 120) by reducing a depletion width of the pn junction. The capacitance of the pn junction can be determined in part by the depletion width of the reverse biased junction, as will be understood by one having ordinary skill in the semiconductor device arts. The depletion width can in turn be determined in part by the concentrations of the dopants that define the pn junction.

The neutralizing species can be a passivating species and/or a displacing species. The neutralizing species can be selected to reduce a concentration of active dopant in the vicinity of the pn junction, to thus increase the depletion width. For example, hydrogen (H) may be used as a passivating species to electronically bind with dopant atoms to deactivate them (the word “hydrogen” is used herein includes isotopes of hydrogen, such as deuterium.) The concentration of neutralizing species in the vicinity of the pn junction can be selected to deactivate a desired portion of dopant.

In general, the depletion width for a particular bias condition will be greater for lower concentrations of dopant. As will be understood by one having skill in the semiconductor device arts, the net concentration of active dopant can have a dominant impact on the depletion width. In particular, at lower concentration levels, a greater depletion width forms to accommodate a particular bias-voltage drop across the pn junction.

In a typical MOS transistor having a heavily doped source or drain, most of the depletion width appears on the lesser doped side of the pn junction. In such a case, the dopant concentration on the substrate side of the pn junction can largely determine the extent of the depletion width. By passivating a portion of the B, for example, in the substrate, the depletion width can be increased and the capacitance thus decreased.

Accordingly, in one example according to principles of the invention, the method 100 is applied to a p-type boron-doped silicon wafer. Source and drain regions are formed by implanting As at a relatively high concentration into the desired regions, followed by annealing to activate at least some of the dopant. Hydrogen is implanted to neutralize a portion of the boron in the substrate neighboring the pn junction, thus reducing the net active dopant concentration in the p-type substrate portion in the vicinity of the source and drain regions. A depletion width at a given voltage condition can thus be greater than would be obtained without introduction of, for example, passivating H, and the capacitance is thus reduced. As described in more detail below, H can be implanted before, during, and/or after implantation of the As.

More generally, according to principles of the invention, the substrate can include a doped silicon layer. For example, the substrate can be a n-type or p-type silicon wafer, made n-type or p-type by incorporation of dopants, such as phosphorus or boron, as known to those having ordinary skill in the semiconductor fabrication arts. The substrate can be, for example, a silicon wafer, which may also incorporate buried insulating layers, in the manner of, for example, a silicon-on-insulator (SOI) wafer, as known to one having ordinary skill in the semiconductor fabrication arts. The neutralizing species can be H or other material that can contribute to passivation and/or displacement of dopant atoms.

In general, it will be preferable to neutralize a portion of a first dopant in the neighborhood of a pn junction rather than simply providing a substrate having a lower concentration of the first dopant. In the latter case, the substrate adjacent to, for example, the channel region of a MOS transistor will then also have a lower concentration of first dopant. Such a transistor can experience, for example, punch-through failure. Thus, according to principles of the invention, an active concentration of a first dopant can be lower in the vicinity of a pn junction while remaining at a higher concentration level in the vicinity of other portions of a device.

The second dopant can be introduced (Step 110) via, for example diffusion or implantation. Implantation can be accomplished via, for example, beam implantation or plasma implantation. The method 100 can further include forming a plasma (Step 111) from a neutralizing material and a dopant material. Plasma implantation can be used, for example, for simultaneous implantation of a dopant species and a neutralizing species. The second dopant can be selectively introduced into the vicinity of a pn junction via, for example, use of a mask, or, for example, via a self-aligned process.

The second dopant can include one or more dopant species, and can be provided by one or more dopant materials (Step 112) that include the dopant species. Some suitable dopant materials include, for example, AsH₃, PH₃, BF₃, AsF₅, PF₃, B₅H₉, and B₂H₆. The neutralizing species can include one or more species provided by one or more neutralizing materials. The neutralizing material can be provided (Step 122) as, for example, a carrier gas in an implantation system. More generally, a carrier gas can be utilized, whether or not it provides a neutralizing species. Some carrier gases include He, Ne, Ar, Kr, and Xe.

Alternatively, in some embodiments, a material provides both a second dopant species and a neutralizing species (Step 132). For example, a neutralizing species can be provided by a doping material. For example, if H is desired as a neutralizing species, some potential doping materials include AsH₃, PH₃, B₅H₉, B₂H₆, and other H-containing materials. Thus, a plasma can be formed from a single material to provide both dopant and neutralizing species. Further, the doping and neutralizing species can be co-implanted, for example, via plasma implantation.

When implantation is used, the second dopant and the neutralizing species can be introduced (Steps 110, 120) via any type of implantation system. Suitable systems include those based on DC, RF and microwave power supplies. Power can be delivered to an implantation systems plasma via, for example, capacitive coupling, inductive coupling, or a waveguide. Multiple implant steps can be used to introduce the second dopant (Step 110) and/or the passivating species (Step 120).

An ion implantater can include, for example, an ion source that converts a gas or a solid material into a well-defined ion beam. An implanter can mass analyze the ion beam to select desired species, and accelerate and direct the beam of desired species at a target area of a substrate. The beam may be distributed over the target area by, for example, beam scanning and/or target movement. A beam implanter can thus provide precise control of dopant species, dopant ion implant energy, and dopant location.

As one alternative to beam implantation, plasma implantation can be used, for example, to exploit its potential lower cost and higher throughput at lower energies. Suitable plasma implantation techniques include, for example, plasma immersion ion implantation (PIII). Plasma implantation can utilize, for example, a continuous or intermittent plasmas, which can be used for continuous or intermittent implantation. In one type of suitable plasma doping system, which utilizes an intermittent plasma, a semiconductor wafer is placed on a conductive platen, which functions as a cathode, located in a plasma doping chamber. An ionizable gas containing a desired material is introduced into the chamber, and a voltage pulse is applied between the platen and an anode to form a glow-discharge plasma having a plasma sheath in the vicinity of the wafer. An applied voltage pulse, for example, can cause ions in the plasma to cross the plasma sheath and to be implanted into the wafer. The depth of implantation can be related to the voltage applied between the wafer and the anode.

Plasma implantation techniques can be used to exploit their capacity to implant species in addition to dopant species. For example, a great variety of neutrals, activated neutrals, and various ions can be implanted into a substrate.

Implantation parameters can be selected to control the location and concentration level of implanted species. For example, a desired effect on the active dopant concentration levels of a pn junction can be achieved in part by selecting an appropriate dose amount and implantation energy. For example, an implant energy may be selected to position an implant in the underlying substrate near to a pn junction. The dose can be selected to provide an amount of a passivating species that will neutralize a significant portion of, but not all of, a first dopant in the underlying substrate adjacent to the junction.

For example, a pn junction depth (below a substrate) can be located at, for example, from about 10 nm to about 100 nm, originating in part from a second dopant as-implanted depth range of from about 5 nm to about 70 nm. A neutralizing species can be implanted, for example, at a depth from about 20 nm to about 200 nm, with some embodiments having a preferred depth of about 2× to about 5× of the target value of a pn junction depth. An implant energy for hydrogen can be, for example, in a range of about 500 eV to about 10 keV. The dose of hydrogen can be, for example, from about 10¹⁴ cm⁻² to about 5×10¹⁵ cm⁻² for a first dopant concentration of about 2×10¹⁸ cm⁻³. In some embodiments, the dose of a neutralizing species, such as hydrogen, scales with concentration of the first dopant.

After introduction of a neutralizing species (Step 120), a substrate can require annealing to permit the neutralizing species to migrate to, and interact with, dopant atoms when, for example, the neutralizing species is introduced via implantation. For example, annealing can permit a H atom to diffuse to, and bond with, a B atom to passivate it. Thus, a passivating species may saturate free bonds of a portion of dopant species atoms to prevent the saturated atoms from contributing free carriers to the semiconductor material. In contrast, a displacing species may displace a dopant atom from an active substitutional lattice site by, for example, collision with the dopant atom during ion implantation, or, for example, by “push-out” of dopant atoms from the substitutional sites during post implantation annealing.

The second dopant and/or the neutralizing species may be introduced (Steps 110, 120) via plasma implantation. The use of plasma implantation techniques can help when fabricating, for example, shallow device junctions. Plasma implantation can provide improved dose rates at lower energies in comparison to a typical ion-beam implanter. For example, at energies under 10 keV (as typically required, for example, for shallow junction formation in sub-90 nm devices) plasma implantation can provide improved throughput for introduction of a second dopant (Step 110).

As described above, plasma implantation can provide simultaneous implantation of dopant and neutralizing species, and the dopant and neutralizing species can be provided by a single implant material. For example, a plasma can be formed from AsH₃. The plasma may include, for example, radicals of AsH₃, AsH₂, AsH, As and H, positive ions of AsH₂, AsH, As and H, and electrons, in addition to unexcited AsH₃ and other molecules and atoms. Arsenic and H can be co-implanted from the plasma. Further, at least some of the co-implanted As and H can be included in a single species provided by the plasma, for example, AsH₂. Thus, an implant species, for example, an ionized molecule, may include both a second dopant and a neutralizing species. Alternatively, an implant species or a dopant species may also act as a neutralizing species, for example by both displacing a portion of a first dopant species in a substrate, and providing a second dopant in the substrate.

If AsH₃ is used as an implant material for co-implantation of As and H, in some embodiments of the invention, the implantation parameters are selected to provide a H dose that is in a range from about 5% of the As dose to about equal to the As dose. The As dose can be selected to be from about 10¹⁴ cm⁻² to about 10¹⁶ cm⁻².

In the case of a MOS transistor, the neutralizing species is introduced (Step 120) after most or all of the processing steps associated with defining areas of the transistor source and drain. That is, it can be preferable to leave the second dopant and neutralizing species as undisturbed as possible after the desired portion of the first dopant has been neutralized. Alternatively, additional neutralizing species such as H can be implanted before or after a second dopant implant. The additional neutralizing species can be implanted with an extraction voltage selected to be, for example, in a range of about 0.2 to about 2 times the level of the extraction voltage used to implant the second dopant.

A dose of a neutralizing species can be selected to neutralize, for example, about 20% to about 90% of a first dopant residing in the substrate underlying a pn junction. As described above, an effective dose will provide sufficient neutralizing species to neutralize enough dopant to have a significant effect on junction capacitance, while not being so greater as to create problems such as punchthrough and leakage. With proper selection of doses, capacitance can be reduced by, for example, about 50%, or up to about 70% or more.

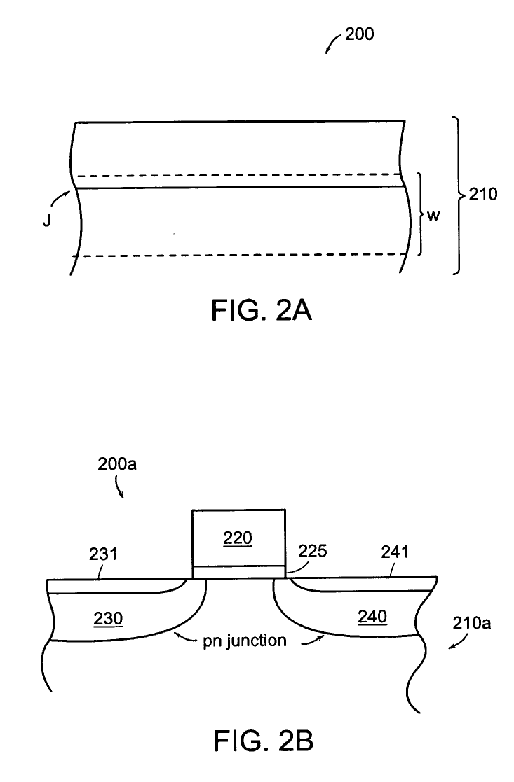

FIG. 2a is a cross-sectional view of an embodiment of a portion of a semiconductor-based device 200, which can be fabricated by, for example, the method 100. The device 200 includes a substrate 210. The substrate 210 includes a semiconductor, first and second dopants that define a pn junction J in the semiconductor, and a neutralizing species local to the pn junction that neutralizes a portion of the first dopant near to the pn junction to decrease a capacitance associated with the pn junction. When a reverse bias is applied to the pn junction, the pn junction is associated with a depletion width W, as illustrated by the dashed lines.

FIG. 2b is a cross-sectional view of an embodiment of a transistor 200a, which can be fabricated by, for example, the method 100. The transistor 200a includes a silicon-based substrate 210a having a first dopant, a source region 230 and a drain region 240 defined by a second dopant, a source contact 231 in contact with the source region 230, a drain contact 241 in contact with the drain region 240, a gate contact 220 adjacent the substrate 210a, and a gate dielectric layer 225 between the gate contact 220 and the substrate 210a. The substrate 210a also includes a neutralizing species, in the vicinity of the source and drain regions 230, 240, that provides an increase in depletion widths of the pn junctions associated with the source and drain regions 230, 240. The neutralizing species is local to the source and drain regions 230, 240, and can be self-aligned with the source and drain regions 230, 240, as will be understood by one having ordinary skill in the semiconductor device fabrication arts.

The source and drain contacts 231, 241 can include silicide. The gate contact 220 can include, for example, a doped conductive polycrystalline silicon lower portion and a silicide upper portion. Alternatively, the gate contact 220 may be formed of another conductive material, such as a heavily doped semiconductor; a metal, e.g., titanium (Ti), tungsten (W), molybdenum (Mo), tantalum (Ta), or iridium (Ir); or metal compounds that provide an appropriate workfunction, e.g., titanium nitride (TiN), titanium silicon nitride (TiSiN), tungsten nitride (WN), tantalum nitride (TaN), tantalum silicide (TaSi), nickel silicide (NiSi), or iridium oxide (IrO₂).

A portion of the substrate may be epitaxially grown, and the first dopant species, such as B, may be incorporated into the epitaxial layer as it is grown. The source and drain contacts 231, 241 can be formed, for example, by depositing a metal layer and reacting the metal layer with the substrate 210a.

The dielectric layer 225 can be formed by various methods conventional in the art, for example, thermal oxidation or a deposition technique. The gate dielectric 225 can be, for example, a 1.0 to 10.0 nm thick layer of silicon dioxide. The dielectric 225, alternatively can be, for example, silicon oxynitride, silicon nitride, a plurality of silicon nitride and silicon oxide layers, or a high-k dielectric. Alternative dielectric materials may be employed when, for example, a thin effective gate oxide thickness is desired, for example, equivalent to an SiO₂ layer thickness of 2.0 nm or less.

The transistor 200a, according to principles of the invention, can be implemented as a NMOS or a PMOS component. The transistor 200a can include, for example, different doping types and levels in source, drain, and channel layer regions.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A method for fabricating a semiconductor-based device, comprising:
providing a substrate comprising a semiconductor and a first dopant;
introducing a second dopant into the substrate, the first and second dopants defining a pn junction in the substrate; and
introducing a neutralizing species into the substrate to reduce a capacitance associated with the pn junction by reducing an electrically active fraction of the first dopant in a vicinity of the pn junction.

2. The method of claim 1, wherein the neutralizing species comprises a passivating species that passivates a portion of the first dopant in the vicinity of the pn junction.

3. The method of claim 1, wherein the neutralizing species comprises a displacing species that displaces a portion of the first dopant from substitutional lattice positions in the vicinity of the pn junction.

4. The method of claim 1, wherein the pn junction is associated with a source of a MOS transistor, and the first and second dopants also define a second pn junction associated with a drain of the MOS transistor.

5. The method of claim 1, wherein introducing the neutralizing species comprises reducing the capacitance by increasing a depletion width associated with the pn junction when in an inversely biased state.

6. The method of claim 1, wherein introducing the second dopant and introducing the neutralizing species occur substantially simultaneously.

7. The method of claim 6, further comprising forming a plasma from the neutralizing species and from at least one compound comprising the second dopant, and wherein introducing the second dopant comprises plasma implanting the second dopant from the plasma, and introducing the neutralizing species comprises plasma implanting the neutralizing species from the plasma.

8. The method of claim 7, wherein the at least one compound comprises at least one compound selected from the group of AsH₃, PH₃, and B₂H₆.

9. The method of claim 1, wherein the passivating species comprises hydrogen.

10. The method of claim 1, wherein the first dopant is B, and the second dopant is selected from the group consisting of P, As, and Sb.

11. The method of claim 1, wherein the second dopant is B, and the first dopant is selected from the group consisting of P, As, and Sb.

12. The method of claim 1, wherein introducing the second dopant comprises implanting the second dopant from a plasma of a type selected from a group consisting of a glow discharge plasma and a RF plasma.

13. The method of claim 12, further comprising forming the plasma in part from a carrier gas comprising the neutralizing species.

14. The method of claim 13, wherein the neutralizing species comprises an inert gas selected from the group of gases comprising He, Ne, Ar, Kr, and Xe.

15. The method of claim 13, wherein forming comprises formingthe plasma from a mixture of the carrier gas and a dopant gas, wherein the neutralizing species is in a range of 0% to 90% of the gas mixture.

16. The method of claim 1, wherein introducing the neutralizing species comprises selecting a dose of the neutralizing species that will neutralizing less than all of the first dopant.

17. The method of claim 16, the dose of the neutralizing species is in a range of about 0.2 times to about 2 times a dose of the second dopant.

18. The method of claim 16, wherein introducing the neutralizing species comprises reducing the active fraction of the first dopant by a factor in a range of about 20% to about 90%.

19. The method of claim 1, wherein introducing the neutralizing species comprises reducing the active fraction of the first dopant to a level at least great enough to effectively prevent punch-through.

20. The method of claim 1, wherein introducing the second dopant comprises providing a peak concentration of the second dopant greater than a peak concentration of the first dopant.

21. The method of claim 1, wherein introducing the neutralizing species comprises selecting an implant depth of the neutralizing species to be associated with a first dopant side of the pn junction.

22. The method of claim 1, wherein providing the substrate comprises introducing the first dopant into the substrate during one of growth of the substrate and after growth of the substrate.

23. A semiconductor-based device fabricated by the method of claim 1.

24. A semiconductor-based device, comprising:
a substrate comprising a semiconductor, first and second dopants that define a pn junction, and a neutralizing species that neutralizes a fraction of the first dopant species in a vicinity of the pn junction to decrease a capacitance associated with the pn junction.

25. The device of claim 24, wherein the pn junction is associated with a source of a transistor.

26. The device of claim 25, wherein the first and second dopant define a second pn junction that is associated with a drain of a transistor.
